(19) United States
(12) Patent Application Publication
(10) Pub. No.: US 2020/0076199 A1
(43) Pub. Date: Mar. 5, 2020

(54) TWO-TERMINAL ELECTRICAL PROTECTIVE DEVICE

(71) Applicant: Pika Energy, Inc., Westbrook, ME (US)

(72) Inventors: Joshua Daniel Kaufman, Gorham, ME (US); Benjamin Francis Polito, Gorham, ME (US)

(21) Appl. No.: 16/561,977

(22) Filed: Sep. 5, 2019

Related U.S. Application Data
(60) Provisional application No. 62/727,435, filed on Sep. 5, 2018.

(51) Int. Cl. H02J 3/38; G05F 3/18; H02J 7/04; H03K 17/081; H02J 7/34

(52) U.S. Cl. CPC H02J 3/383; G05F 3/18; H02J 2007/0037; H03K 17/08116; H02J 7/34; H02J 7/04

(57) ABSTRACT

An electrical circuit includes a switch, an energy harvesting circuit coupled to the switch to collect power from the voltage drop across the switch, and a control circuit coupled to the energy harvesting circuit to maintain the switch in an ‘on’ state in response to current flow through the switch and to turn off the switch in response to no current flow through the switch.

### RELATED APPLICATION

This application claims priority to U.S. Provisional Application Ser. No. 62/727,435 (entitled TWO-TERMINAL ELECTRICAL PROTECTIVE DEVICE, filed Sep. 5, 2019) which is incorporated herein by reference.

### BACKGROUND

By their nature, photovoltaic (PV) solar arrays and energy storage battery stacks present continuous voltage and significant available power at their terminals, and so it may be desirable to provide switching capability, to meet safety or compliance needs. This can be accomplished with active switching devices, relays, or electromechanical contactors, but these require extra wiring and may involve significant continuous power consumption to operate.

### SUMMARY

A two-terminal electrical protective device operates by harvesting energy from a small but non-zero voltage drop across a closed solid-state switch. From a default, open-circuit state, the device may be remotely triggered by an AC signal to enter the desired conductive state. Power scavenged by an energy harvesting circuit while the device is in the conductive state, powers a gate drive circuit to hold the device in the conductive state for as long as current flows. When current stops, the device returns to the default open-circuit state.

One or more such devices can be interspersed between or integrated with PV modules, energy storage battery modules, fuel cells, or other distributed energy devices, as a simple way to ensure safety and compliance. Advantages may include very low power consumption, low series resistance, and avoidance of the need for separate conductors to drive the switch, which may be remotely located.

A two-terminal device with low voltage drop can be triggered remotely into a conductive mode and latched in the ‘on’ state until current flow ceases.

In addition to solar and battery applications, other potential applications include remote disconnection for DC distribution networks.

### BRIEF DESCRIPTION OF THE DRAWINGS

FIG. 1 is a functional block diagram of protection circuit according to an example embodiment.

FIG. 2 is a schematic view of one embodiment of the device according to an example embodiment.

FIG. 3 shows an alternative embodiment of the device featuring an alternative low-cost gate drive circuit, overvoltage protection and resonant signal filter according to an example embodiment.

FIG. 4 shows a simplified design requiring continuous signaling according to an example embodiment.

FIG. 5 is a block schematic representation of an example implementation in a PV power system.

FIG. 6A is a block perspective representation of a physical implementation of a protection circuit implementation according to an example embodiment.

FIG. 6B is a more compact block perspective representation of a physical implementation of a protection circuit implementation according to an example embodiment.

FIG. 6C is a block perspective representation of a protection circuit coupled to a PV module according to an example embodiment.

FIG. 7 is a block diagram of a computing system for use in controlling one or more devices according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software in one embodiment. The software may consist of computer executable instructions stored on computer readable media or computer readable storage device such as one or more non-transitory memories or other type of hardware-based storage devices, either local or networked. Further, such functions correspond to modules, which may be software, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system, turning such computer system into a specifically programmed machine.

The functionality can be configured to perform an operation using, for instance, software, hardware, firmware, or the like. For example, the phrase “configured to” can refer to a logic circuit structure of a hardware element that is to implement the associated functionality. The phrase “configured to” can also refer to a logic circuit structure of a hardware element that is to implement the coding design of associated functionality of firmware or software. The term “module” refers to a structural element that can be implemented using any suitable hardware (e.g., a processor, among others), software (e.g., an application, among others), firmware, or any combination of hardware, software, and firmware. The term, “logic” encompasses any functionality for performing a task. For instance, each operation illustrated in the flowcharts corresponds to logic for performing that operation. An operation can be performed using, software, hardware, firmware, or the like. The terms, “component,” “system,” and the like may refer to computer-related entities, hardware, and software in execution, firmware, or combination thereof. A component may be a process running on a processor, an object, an executable, a program, a function, a subroutine, a computer, or a combination of software and hardware. The term, “processor,” may refer to a hardware component, such as a processing unit of a computer system.

Furthermore, the claimed subject matter may be implemented as a method, apparatus, or article of manufacture using standard programming and engineering techniques to produce software, firmware, hardware, or any combination thereof to control a computing device to implement the disclosed subject matter. The term, “article of manufacture,” as used herein is intended to encompass a computer program accessible from any computer-readable storage device or media. Computer-readable storage media can include, but are not limited to, magnetic storage devices, e.g., hard disk, floppy disk, magnetic strips, optical disk, compact disk (CD), digital versatile disk (DVD), smart cards, flash memory devices, among others. In contrast, computer-readable media, i.e., not storage media, may additionally include communication media such as transmission media for wireless signals and the like.

Many installations of solar photo voltaic devices, such as solar panels involve connecting multiple panels in series. Such a series connection can result in high voltages being present in the installation should current flow be stopped. Switches between the panels can be used to create open circuits between the panels to reduce the risk of such high voltages occurring.

Solid-state devices can be used to perform a switching function between panels. Silicon-controlled rectifiers (SCRs) have the capability of latching current conduction for as long as the current flow continues. However, they typically present over 1.5V of voltage drop across the device, which causes significant and unacceptable power loss in many applications. Other solid-state switches (e.g. MOSFETs, IGBTs and BJTs) can have significantly lower voltage drop resulting in higher efficiency system designs, but they don't exhibit latching behavior and so must be continuously powered.

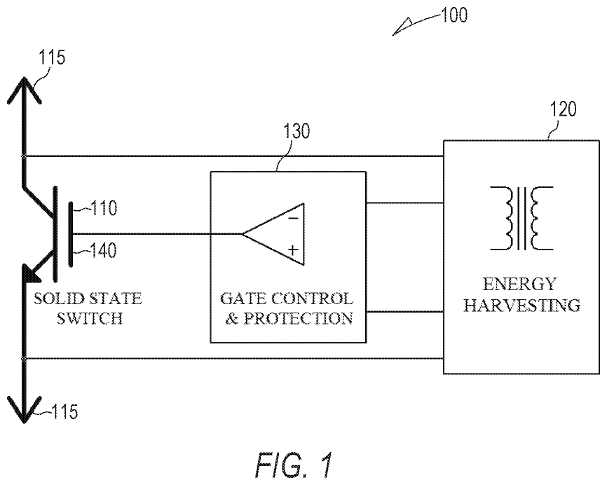

FIG. 1 illustrates a block functional diagram of an example protective device 100. Current flow in a primary current path is controlled in a circuit by the solid-state switch 110, for instance a MOSFET, IGBT or BJT. The current flow is indicated by arrows 115 on the conductors on either side of the switch 110. Even in the on state, the switch 110 has some nonzero voltage drop across it, and therefore energy can be harvested as indicated by an energy harvesting circuit 120 coupled across the switch. The energy harvesting circuit 120 creates a supply at a sufficient voltage to power a gate control and protection circuit 130, which in turn drives the gate of the device to the ‘on’ state.

In an initial high-impedance ‘off’ state, the primary current flow is blocked, and no energy is harvested. The gate 140 voltage is too low to turn on the switch 110. An AC signal, typically a current between 1 mA and 1 A at 10 kHz up to 10 MHz, may be applied through the device 100 (or through a number of such devices connected in series). Although the device 100 is high impedance to DC current, it may be configured to allow a high frequency AC current signal to pass through for activation. The AC signal activates the energy harvesting circuit to power the gate control circuit, which drives the switch to the on state. The energy harvesting circuit harvests sufficient power from the steady-state voltage drop across the switch (while the switch is ‘on’ and conductive) to power the gate control and protection circuit 130, latching the device in the low-impedance state to the current flow indicated by the arrows 115.

The power requirement to turn on the switch can be designed to be quite low. For instance, the small voltage drop across the primary switch in the on state may be boosted by an energy harvesting circuit 220 to form a power supply. Alternatively, the device may be powered by a small auxiliary photovoltaic cell, wirelessly transmitted RF power, or another means as described below. In other embodiments, it may be advantageous to power the protective device from a low-amplitude AC signal superimposed on the overall circuit, and the protective device may be made capable of conducting such an AC signal while blocking hazardous voltage and the flow of bulk power.

It may be advantageous for the protective device to respond to a remotely-initiated signal, for instance a shutdown signal sent to a rooftop PV array by a public safety worker at ground level. This signal may be the presence or absence of a low-amplitude AC waveform conducted by the circuit being protected and applied across the terminals of the protective device, with or without some form of encoding. Alternatively, the signal may take the form of a wireless RF signal transmitted from a nearby base station, for instance at a central inverter location, a wireless IR signal, or other means, and detected by the protective device or devices.

In some implementations it may be advantageous to require the continuous presence of the ‘operate’ signal to maintain the switch in the conductive state. In others it may be desired that the device latch in the conductive state and/or non-conductive state. In some embodiments it may be advantageous for the protective device to latch in the conductive state, for example in response to a low-amplitude AC signal and remain in the conductive state until the flow of current ceases—for instance after a ground-level disconnect switch is opened or an inverter is disabled. At that point the protective device may latch in the non-conductive (safe) state until the AC signal is re-applied. In other implementations it may be further desired that the device may be latched back into high impedance state by a different signal.

In some applications, such as battery arrays or DC nanogrids/microgrids, it may be advantageous to use a bi-directional switch capable of interrupting current flow in both directions. It may be advantageous for various implementations to have several internally protective features as described below.

The control terminal of the solid-state switch may be regulated by a feedback circuit involving op-amps and/or transistors to maintain sufficient voltage drop across the device for the energy harvesting circuit 120 to operate. In one embodiment, the voltage across the solid-state switch is amplified and fed into the control terminal e.g. the gate of the MOSFET. In this way, the device 100 can stay powered even with very small current through the switch 110.

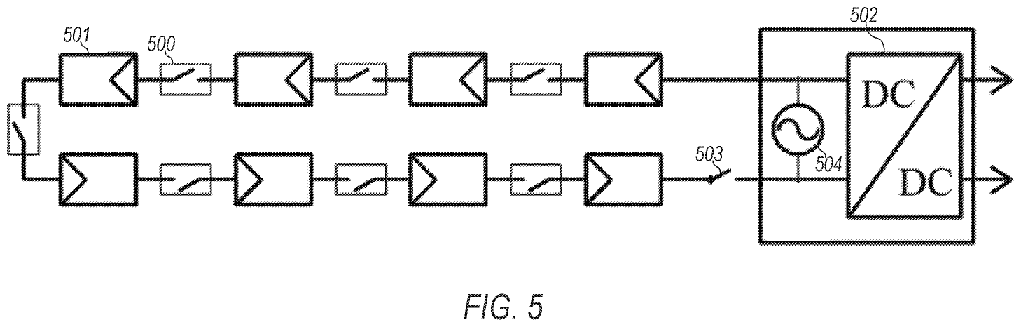

In the event of a shutdown signal or other need to return the device 100 to the high impedance state, the current flow is stopped, such as bringing the current flow to zero or at least low enough to place the switches in the high impedance state. In one or more embodiments, a master switch, such as a remote power converter, conveniently-located switch (e.g. 503 in FIG. 5), circuit breaker, or fuse opens, whereupon the energy harvest circuit 120 ceases operation, and the device 100 latches in the high-impedance state. As shown in FIG. 5, the remote power converter may be a DC optimizer or inverter into which the string of PV or other voltage sources feeds. Any mechanism that stops the current flow is then able to put the disconnect switches back into the high impedance state.

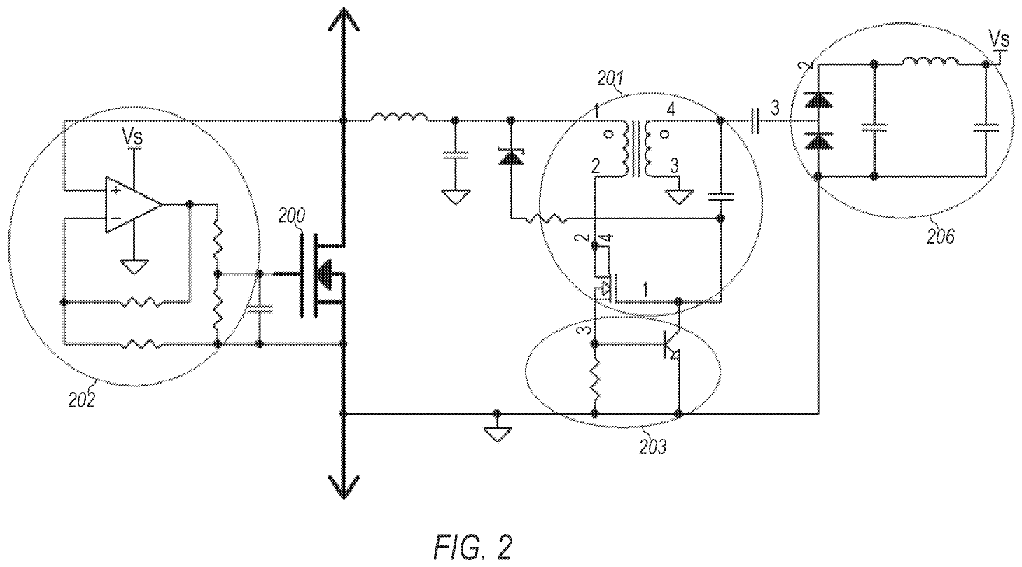

FIG. 2 is a schematic diagram of one embodiment of the device. This implementation uses a resonant converter 201 with high-turns-ratio transformer, typically 1:50 to 1:200, for converting the tens to hundreds of millivolts drop across the device into a supply voltage of several volts, Vs, sufficient to drive the switch control signal of the primary switch 200. An op amp circuit 202 controls the gate of the primary switch 200 and is configured to maintain a substantially constant voltage drop across the transistor.

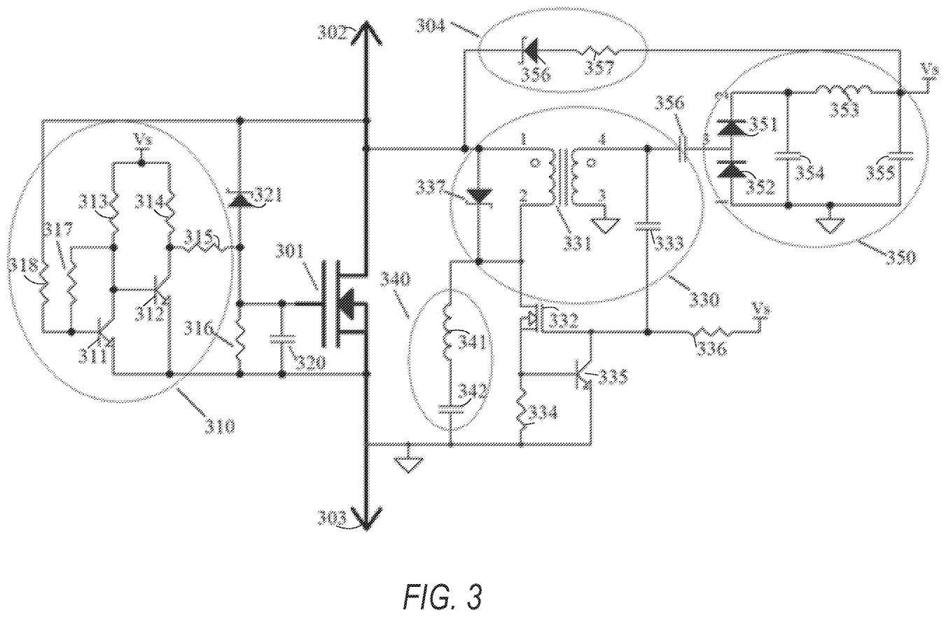

A challenge solved by this design is that the energy harvesting converter should effectively operate over a wide range of input voltages. A switching converter designed to operate at a few tenths of a volt may suffer overcurrent at tens of volts. In one embodiment, high speed overcurrent protection is provided for the main energy harvesting converter 201. FIG. 2 shows how this can be accomplished with a bipolar transistor with the base connected to a current sense resistor 203 (and 303 in FIG. 3). The rectifier circuit 206 (and 350 in FIG. 3) converts the AC output of the transformer to a DC supply for powering the gate control circuit 202 (and 310 in FIG. 3).

Another challenge solved by one or more embodiments is how to avoid the use of unnecessarily high-voltage power silicon which increases cost and reduces efficiency. The danger to the solid-state switch product is that a series-string of voltage sources and disconnect switches would apply the entire string voltage to a single switch in the condition that only one switch is in the ‘off’ state. However, using switches rated for the entire string voltage would compromise the system efficiency and cost. One potential solution to this problem is to have switches immediately turn on before they avalanche. This can be achieved with a Zener diode 304 to trigger the energy harvesting power converter 330 as shown in FIG. 3. FIG. 3 also features a Zener diode 321 coupled to a gate drive circuit 302 used to directly turn the switch on. In some embodiments a single Zener diode achieves both functionalities.

One function of a disconnect system is the ability to simultaneously trigger multiple disconnects in a series or series-parallel string to cause them to change state. One approach for causing the disconnects to change to the low impedance state is to apply a small AC current signal to the series string. Although the string is high impedance to DC current, a small amount of AC current can pass through and be used to activate the energy harvesting circuit. This AC current can pass through a low impedance capacitor or a band-pass filter to reduce the chances of unintentional activation. FIG. 3 includes a resonant signal filter 340 to help prevent the switch from turning on in the presence of noise. Once the energy harvesting circuit has been activated it will continue to operate and keep the switch in the conductive state.

To cause the disconnects to return to the high impedance state, the string current is reduced to below the level required to maintain the energy harvesting convertor 330, typically a few milliamps. It then shuts down and the solid-state switches latch in a high impedance state.

FIG. 3 also presents a lower-cost gate drive circuit incorporating inexpensive bipolar transistors 302 instead of an op amp in the protective device. In one embodiment, a protective device includes a primary current path with solid state primary switch 301 positioned to break the flow of current between terminals 302, 303. The device incorporates a gate control circuit 310, an energy harvesting circuit 330, AC bypass circuit 340, and power supply 350.

Primary switch 301 may be chosen for low on resistance/voltage drop, for instance a N-channel MOSFET with current carrying capacity sufficient for the application. When powered by supply 350, gate control circuit 310 serves to stabilize the voltage drop across primary switch 301 at a level low enough to minimize energy loss in the switch, but high enough to operate energy harvest circuit 330. The gate control circuit comprises a feedback circuit formed by transistors 311, 312; bias resistors 313, 314, 317 and voltage sense resistor 318. Resistors 315 and 316 with capacitor 320 and including any gate capacitance of the main switch set the low-pass frequency response of the gate drive.

Overvoltage protection zener diode 321 can quickly turn the gate on in the event of high voltage across the main switch. In operation, from a hypothetical initial high impedance state, when the power supply voltage Vs gets above the gate threshold voltage of the main switch, bias resistors 314 and 315 tend to turn on switch 301 by charging its gate. More than a few hundred millivolts of drain to source voltage across the main switch, keeps transistor 311 in a conduction state and pulls down the base of transistor 312, further biasing 301 on. However, if the voltage falls below the level desired for energy harvest, conduction decreases in transistor 311, allowing 312 to pull down the gate of 301, thereby stabilizing the voltage drop across 301 at a low level. The equilibrium drain to source voltage drop in the conducting state is determined by the relative values of the circuit components, and may be selected by experiment or analysis.

The voltage sense resistor 318 is chosen with very high impedance, typically tens of megaohms, because this will set a minimum of the DC impedance of the complete circuit when the main switch is off. Because the conducted current in transistor 311 is so low, resistor 313 will also need to be megaohms to give a practical gain for controlling the base of transistor 312. Resistor 317 pulls up the base of transistor 311 so that it conducts when the voltage across the main switch is tens of millivolts rather than the hundreds of millivolts typically required to get significant conduction through a BJT transistor. Upon loss of power from supply 350, switch 301 transitions directly to its high-impedance state at a controlled rate determined by the values of capacitor 320, the gate capacitance of the main switch and resistor 316. It will stay high impedance for as long as supply voltage Vs is below its gate threshold voltage.

In the event that a voltage is applied across the device is in excess of the drain-source voltage rating of switch 301, zener diode 321 conducts to force the gate of 301 into conduction, protecting the device by allowing the current to flow. This allows switch 301 to have a voltage rating much lower than the aggregate voltage of all sources in a series string, resulting in significantly lower energy losses in the protective devices. Ideally the design will cause the main switch to turn on only after the supply voltage has been charged through zener diode 356 and resistor 357. This allows the resonant converter to start oscillating and latch the switch into a conductive state rather than limit cycling as the drain-source voltage bounces.

Energy harvesting circuit 330 is designed to operate on the voltage drop across switch 301. Circuit 330 comprises a resonant converter built from transformer 331, switch 332, and capacitor 333. In operation, conduction in switch 332 ramps current in the primary of 331, inducing current flow in the secondary through the capacitor, pulling down the gate of switch 332 and stopping the flow of current. Stored energy in the leakage inductance of the transformer primary causes the voltage on the drain of switch 332 until current flow reverses in the transformer primary causing current flow in the secondary to charge the gate of switch 332 and repeat the cycle. The resulting oscillation has a resonant frequency at approximately the LC resonance of the magnetizing inductance of the transformer secondary and the capacitance of 333. A high turns ratio (e.g. 1:50 to 1:200) in transformer 331 delivers an AC waveform capable of powering the gate control circuit 310 via the power supply circuit 350, comprising a rectifier bridge of diodes 351 and 352, capacitors 354, 355, and inductor 353 which produces a smooth DC supply for gate control circuit 310.

From an initial resting state, the energy harvest circuit may be brought into operation remotely, for example by an AC signal applied to the overall power circuit, which directly energizes the power supply circuit 350 through transformer 331. Resonant bypass filter 340 formed of inductor 341 and capacitor 342 may be tuned to readily pass the AC signal across a string of several protective devices in series and provide a degree of rejection to spurious signals. Further noise immunity is provided by resistor 336, which prevents spontaneous oscillation of the resonant converter until the power supply is brought up by the external AC signal. In contrast, if the protective device is in a high impedance state and a voltage in excess of the rating of switch 301 is applied, Zener diode 356 quickly brings up the power supply through resistor 357 to enable the switch to go into conduction.

An overcurrent protection circuit formed by current sense resistor 334 and transistor 335 enables the energy harvest circuit to operate across a very wide range of voltages without excessive current flow. High current in the primary of transformer 331 causes a voltage drop across resistor 334 which in excess of a few hundred millivolts turns on transistor 335, which limits conduction in switch 332.

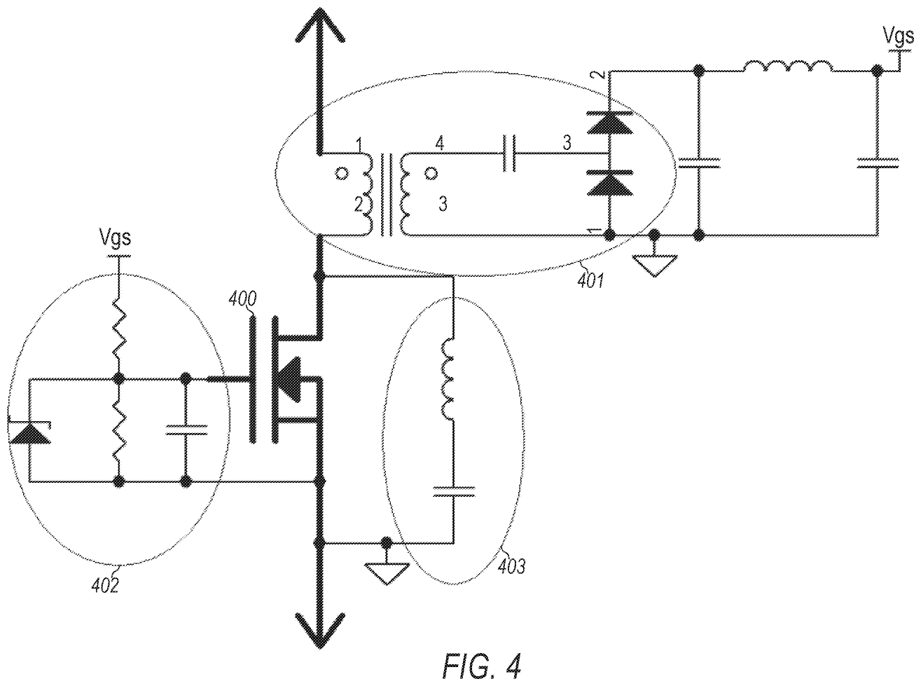

FIG. 4 shows a simplified design utilizing continuous signaling to maintain the switch in a low impedance state. A series transformer 401 picks up a continuous signal to create a power source that uses a gate drive network 402 to maintain the solid-state switch 400 in its on state. A filter circuit 403 limits the frequencies that can be used to activate the power supply circuit.

Most or all of the energy harvesting and control circuitry could be incorporated into an ASIC for smaller size and lower cost. This ASIC could incorporate more advanced decoding, such as FSK (frequency shift keying) data, for robustness against noise.

In some instances, it may be advantageous for code compliance or other considerations for the protective device to require a continuous signal to remain in the conductive state. In some embodiments, the two-terminal protective device such as in FIG. 4 may be continuously held in conductive state by a remote signal, such as an AC signaling current applied across the terminals of the device. Transformer 410 amplifies a low-amplitude AC signal to create a power source, Vgs, that powers gate drive network 402 to maintain switch 400 in a low-impedance state. A filter circuit 403 facilitates transmission of the AC signaling current while limiting the passage of other frequencies. Upon loss of AC signal, the gate drive circuit is de-powered, and the switch 400 goes into the high-impedance protective state until the signal is restarted. While not shown, the implementation of FIG. 4 can be provided with the overvoltage protection and other protective features described in FIG. 3 and elsewhere herein. In some implementations, more sophisticated encoding of the AC signal (e.g. frequency shift keying) may be implemented for additional robustness and security.

A challenge of the solar photovoltaic industry is to meet PV Rapid Shutdown requirements effectively prescribing that every solar PV module be separately disconnected during emergency shutdown events. One approach is to put a power converter on every module which increases cost and reduces reliability and safety. String inverters accept power input from many modules reducing the system cost but are unable to disconnect every module from each other as required by new codes. FIG. 5 demonstrates a solution that uses multiple switches 500 described above and coupled between PV solar array modules 501 to allow string inverters or DC optimizers 502 to disconnect each module 501 without the addition of expensive power converters. An optional switch 503 may be manually or controller controlled to create an open or closed circuit. A high frequency AC source 504 may be used to place the switches 500 in an on, conducting state on startup. The frequency of the AC source should be high enough to not be filtered out and will be dependent on component values.

In one example application, protective devices 501 may be installed between each PV module 501 of a series-connected string, with the string feeding e.g. the DC/DC substring converter 502 or central string inverter. In this configuration, when the protective devices are in the high-impedance state, dangerous voltages cannot be accessed anywhere in the string. To bring the string into conduction, a switchable low-voltage source 504 applies an AC signal across the terminals of the string, at a frequency well suited to be conducted through the internal capacitance of the PV modules and the internal resonant bypass circuits of the protective devices. In response to this signal, the power supply within each device is energized, the primary switch goes into conduction, and the resonant energy harvest circuit latches the device in the conductive state.

While all devices respond to the same AC signal, it is inevitable that some devices will come into conduction faster than others, and under some conditions a device that switches late may be exposed to the full string voltage. However, the overvoltage protective features illustrated in FIG. 4 brings the protective device into conduction, protecting it from damage until its resonant energy harvest circuit and gate control circuit power up to latch it on. In this way, the protective devices can essentially cooperate to withstand the combined voltage of all the PV modules in the string, and the primary switch of each protective device need not carry a voltage rating capable of withstanding the total string voltage, but rather need only be rated comfortably in excess of the maximum voltage expected from each PV module. This may significantly reduce the series resistance and thus the energy loss from the protective system as a whole.

In some embodiments, the string may be put in a high-impedance state by momentarily interrupting the current flow in the circuit. This will cause the voltage drop across the primary switch of each protective device to fall to zero, the energy harvest circuit to cease operation, and the device to latch in the high-impedance state. The current flow can be interrupted by simply ceasing the operation of the power converter that is harvesting the output of the string, or by opening a manual or automatic disconnect switch (e.g. 504). Even if the switch is subsequently closed, the string will remain in the high-impedance state until the AC signal is reapplied.

One of the advantages of the protective device described here is compact size and simplicity of installation. The device may be packaged in a compact, lightweight weatherproof shell, which may be integrated with industry-standard connectors, PV module junction boxes, or other system components.

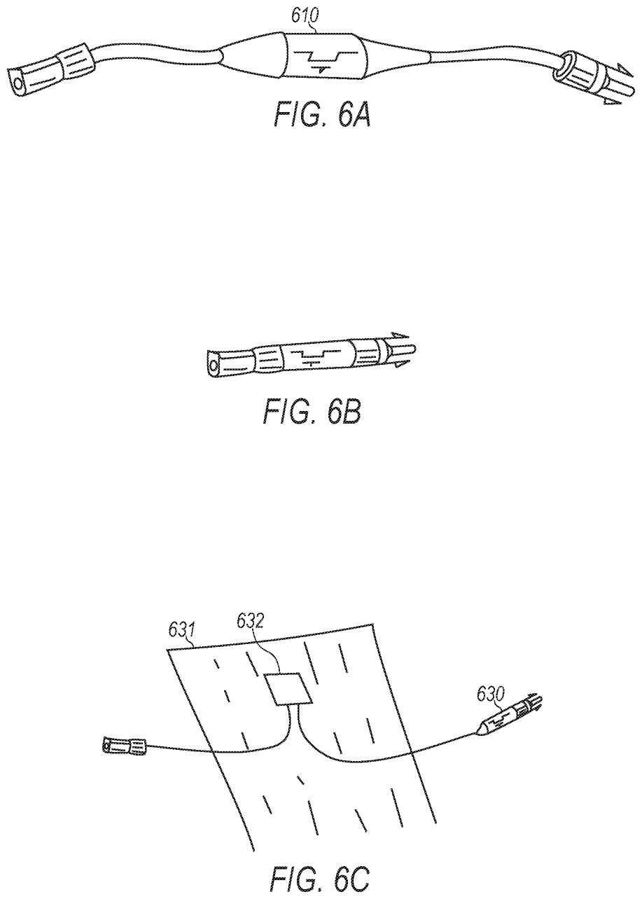

FIG. 6A illustrates a robust physical implementation of the two-terminal protective device, incorporating the device 610 into a whip with standard cabling and connectors as are used in the solar industry. FIG. 6B illustrates a more compact implementation. The simplicity of installation may be further enhanced by incorporation into existing components of a solar energy system. FIG. 6C illustrates a protective device 630 integrated into one connector of a PV module 631. The protective device could also be incorporated into cabling, junction boxes 632, or the module 631 itself.

While in the example of FIG. 4 the enabling AC signal also delivers the power to operate the gate drive circuit, in other implementations the continuous enablement signal may be transmitted as described here, while power may be harvested from the voltage drop across the primary switch as in FIG. 3, transmitted wirelessly, generated by a small ancillary PV cell picking up ambient light, or provided by another means adapted to provide a small amount of power wirelessly, and such power may be stored in capacitors or a small electrochemical battery.

In still other implementations, the signal may be transmitted wirelessly by RF, infrared, or another signaling means. The concepts presented may be applied in various combinations and may be integrated into a custom integrated circuit (ASIC), all without deviating from the inventive subject matter.

The following statements are potential claims that may be converted to claims in a future application. No modification of the following statements should be allowed to affect the interpretation of claims which may be drafted when this provisional application is converted into a regular utility application.

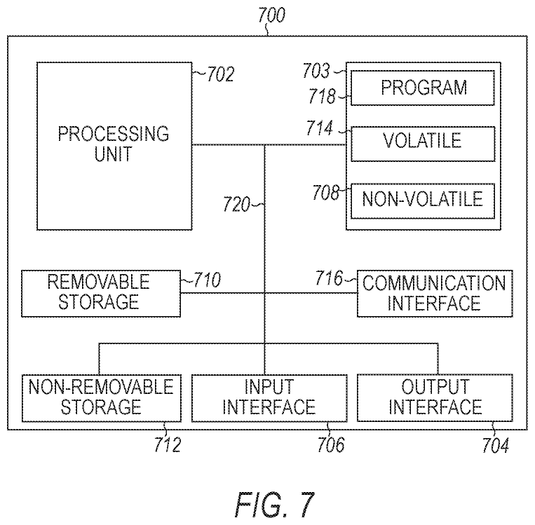

FIG. 7 is a block schematic diagram of a computer system 700 to control one or more devices described herein. All components need not be used in various embodiments.

One example computing device in the form of a computer 700 may include a processing unit 702, memory 703, removable storage 710, and non-removable storage 712. Although the example computing device is illustrated and described as computer 700, the computing device may be in different forms in different embodiments. For example, the computing device may instead be a smartphone, a tablet, smartwatch, smart storage device (SSD), or other computing device including the same or similar elements as illustrated and described with regard to FIG. 7. Devices, such as smartphones, tablets, and smartwatches, are generally collectively referred to as mobile devices or user equipment.

Although the various data storage elements are illustrated as part of the computer 700, the storage may also or alternatively include cloud-based storage accessible via a network, such as the Internet or server based storage. Note also that an SSD may include a processor on which the parser may be run, allowing transfer of parsed, filtered data through I/O channels between the SSD and main memory.

Memory 703 may include volatile memory 714 and non-volatile memory 708. Computer 700 may include—or have access to a computing environment that includes—a variety of computer-readable media, such as volatile memory 714 and non-volatile memory 708, removable storage 710 and non-removable storage 712. Computer storage includes random access memory (RAM), read only memory (ROM), erasable programmable read-only memory (EPROM) or electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions.

Computer 700 may include or have access to a computing environment that includes input interface 706, output interface 704, and a communication interface 716. Output interface 704 may include a display device, such as a touchscreen, that also may serve as an input device. The input interface 706 may include one or more of a touchscreen, touchpad, mouse, keyboard, camera, one or more device-specific buttons, one or more sensors integrated within or coupled via wired or wireless data connections to the computer 700, and other input devices. The computer may operate in a networked environment using a communication connection to connect to one or more remote computers, such as database servers. The remote computer may include a personal computer (PC), server, router, network PC, a peer device or other common data flow network switch, or the like. The communication connection may include a Local Area Network (LAN), a Wide Area Network (WAN), cellular, Wi-Fi, Bluetooth, or other networks. According to one embodiment, the various components of computer 700 are connected with a system bus 720.

Computer-readable instructions stored on a computer-readable medium are executable by the processing unit 702 of the computer 700, such as a program 718. The program 718 in some embodiments comprises software to implement one or more . . . . A hard drive, CD-ROM, and RAM are some examples of articles including a non-transitory computer-readable medium such as a storage device. The terms computer-readable medium and storage device do not include carrier waves to the extent carrier waves are deemed too transitory. Storage can also include networked storage, such as a storage area network (SAN). Computer program 718 along with the workspace manager 722 may be used to cause processing unit 702 to perform one or more methods or algorithms described herein.

### EXAMPLES

1. An electrical circuit includes a switch, an energy harvesting circuit coupled to the switch to collect power from the voltage drop across the solid-state switch, and a control circuit coupled to the energy harvesting circuit to maintaining the solid-state switch in an ‘on’ state.

2. The circuit of example 1 wherein the control circuit controls the solid-state switch to maintain a minimum voltage for feeding the energy harvesting circuit over a wide range of currents through the solid-state switch.

3. An electrical circuit includes at least one solid-state switch, an energy harvesting circuit for collecting power from the AC current passing through the at least one solid-state switch, and a control circuit for maintaining the at least one of the solid-state switches in an ‘on’ state.

4. A method includes using a series disconnect switch for a DC power system and activating the series disconnect switch via an AC signal passing through a DC series string of the DC power system.

5. The method of example 4 where the disconnect switch latches into a conductive state until current flow through it ceases.

6. The method of any of examples 5-4 where the disconnect switch remains in a conductive state while the AC signal current is present.

7. A method of protecting a low-voltage solid-state switch in a high-voltage series string by putting the switch into a conductive state.

8. An electrical circuit includes a switch having an input, output, and control gate, an energy harvesting circuit coupled to the input and output of solid-state switch to collect power from a voltage drop across the solid-state switch, and a gate control circuit coupled to the energy harvesting circuit and the control gate of the switch to maintain the switch in an ‘on’ state in response to power received from the energy harvesting circuit.

9. The circuit of example 8 wherein the gate control circuit controls the switch to maintain a minimum voltage for feeding the energy harvesting circuit over a wide range of currents through the switch.

10. The circuit of any of examples 8-9 wherein the switch is in an open state with no voltage applied to the control gate.

11. The circuit of any of examples 8-10 wherein the switch comprises a solid-state switch.

12. The circuit of any of examples 8-11 wherein the control circuit controls the switch to maintain a minimum voltage for feeding the energy harvesting circuit over a wide range of currents through the input and output of the switch.

13. The circuit of any of examples 8-12 wherein the energy harvesting circuit comprises a resonant converter having a turns ratio sufficient to convert the voltage drop for the control circuit to keep the switch in an on state while current is flowing through the switch.

14. The circuit of any of examples 8-13 and further comprising a zener diode coupled between the energy harvesting circuit and the input to cause the switch to turn on prior to avalanche.

15. The circuit of any of examples 8-14 and further comprising a rectifier coupled to the energy harvesting circuit that activates the energy harvesting circuit in response to an AC signal across the switch.

16. The circuit of any of examples 8-15 and further comprising a resonant filter coupled between the energy harvesting circuit and the switch to prevent turn on due to noise.

17. The circuit of any of examples 8-16 wherein the switch is configured to latch to a high impedance state in response to low current across the switch resulting in a low voltage at the gate of the switch.

18. A system includes a plurality of photovoltaic (PV) modules coupled in series and a plurality of switches coupled between pairs of the PV modules in series. At least one of the switches comprises a switch having a high impedance latchable state, an energy harvesting circuit coupled to the switch to collect power from the voltage drop across the switch, and a control circuit coupled to the energy harvesting circuit to maintaining the solid-state switch in an ‘on’ low impedance state.

19. The system of example 18 and further comprising a master switch coupled to the series string of PV modules and switches, the master switch capable of stopping current flow in the series string.

20. The system of example 19 wherein the switches latch to the high-impedance state in response to the master switch stopping current flow.

21. A method includes harvesting energy from a disconnect switch while DC current is flowing through the switch, generating a supply voltage from the harvested energy, applying a voltage to a control gate of the disconnect switch, the supply voltage being generated by a control circuit coupled to the supply voltage, and placing the disconnect switch in a high impedance state in response to a lack of DC current flowing through the switch.

22. The method of example 21 and further comprising placing a disconnect switch in a conductive state in response to an AC signal applied to the disconnect switch.

23. An electrical circuit includes a switch, an energy harvesting circuit coupled to the switch to collect power from the voltage drop across the switch, and a control circuit coupled to the energy harvesting circuit to maintain the switch in an ‘on’ state in response to current flow through the switch and to turn off the switch in response to no current flow through the switch.

24. The circuit of example 23 wherein the control circuit controls the solid-state switch to maintain a minimum voltage for feeding the energy harvesting circuit over a wide range of currents through the solid-state switch.

25. The circuit of any of examples 23-24 wherein the control circuit controls the switch to maintain a minimum voltage for feeding the energy harvesting circuit over a wide range of currents through the input and output of the switch.

26. The circuit of any of examples 23-25 wherein the energy harvesting circuit comprises a resonant converter having a turns ratio sufficient to convert the voltage drop for the control circuit to keep the switch in an on state while current is flowing through the switch.

27. The circuit of any of examples 23-26 and further including a Zener diode coupled between the energy harvesting circuit and the input to cause the switch to turn on prior to avalanche.

28. The circuit of any of examples 23-27 and further including a rectifier coupled to the energy harvesting circuit that activates the energy harvesting circuit in response to an AC signal across the switch to turn on the switch.

29. The circuit of any of examples 23-28 and further including a resonant filter coupled between the energy harvesting circuit and the switch to prevent turn on due to noise.

30. The circuit of any of examples 23-29 wherein the switch includes a solid-state switch.

31. The circuit of any of examples 23-30 wherein the switch is configured to latch to a high impedance state in response to low current across the switch resulting in a low voltage at the gate of the switch.

32. A system includes a plurality of photovoltaic (PV) modules and a plurality of protective devices, each protective device coupled in series between two of the PV modules, forming an alternating series of PV modules and protective devices. The protective devices comprise a switch having a high impedance latchable state, an energy harvesting circuit coupled to the switch to collect power from the voltage drop across the switch, and a control circuit coupled to the energy harvesting circuit to maintain the switch in an ‘on’ low impedance state in response to current flow through the switch and to turn off the switch in response to no current flow through the switch.

33. The system of example 32 and further including a master switch coupled to the series string of PV modules and switches, the master switch capable of stopping current flow in the series string.

34. The system of example 33 wherein the switches latch to the high-impedance state in response to the master switch stopping current flow.

35. The system of any of examples 32-34 wherein the energy harvesting circuits include a resonant converter having a turns ratio sufficient to convert the voltage drop for the control circuit to keep the switch in an on state while current is flowing through the switch.

36. The system of any of examples 32-35 and further including a Zener diode coupled between the energy harvesting circuit and the switch to cause the switch to turn on prior to avalanche.

37. The system of any of examples 32-36 and further including a rectifier coupled to the energy harvesting circuit that activates the energy harvesting circuit in response to an AC signal across the switch to turn on the switch and a resonant filter coupled between the energy harvesting circuit and the switch to prevent turn on due to noise.

38. A method comprising harvesting energy from a disconnect switch while DC current is flowing through the switch, generating a supply voltage from the harvested energy, applying a voltage to a control gate of the disconnect switch, the supply voltage being generated by a control circuit coupled to the supply voltage, and placing the disconnect switch in a high impedance state in response to a lack of DC current flowing through the switch.

39. The method of example 38 and further including placing a disconnect switch in a conductive state in response to an AC signal applied to the disconnect switch.

40. The method of example 39 wherein the AC signal has a current between 1 mA and 1 A at 10 kHz up to 10 MHz.

41. The method of any of examples 38-40 wherein the lack of DC current is caused by using a master switch to create an open circuit in a series connected string of alternating protective devices that include switches and photo voltaic modules.

42. The method of any of examples 38-41 and further including using a Zener diode coupled to the switch to cause the switch to turn on prior to avalanche and using a resonant filter to prevent switch turn on due to noise.

Although a few embodiments have been described in detail above, other modifications are possible. For example, the logic flows depicted in the figures do not require the particular order shown, or sequential order, to achieve desirable results. Other steps may be provided, or steps may be eliminated, from the described flows, and other components may be added to, or removed from, the described systems. Other embodiments may be within the scope of the following claims.

1. An electrical circuit comprising:
a switch;
an energy harvesting circuit coupled to the switch to collect power from the voltage drop across the switch; and
a control circuit coupled to the energy harvesting circuit to maintain the switch in an ‘on’ state in response to current flow through the switch and to turn off the switch in response to no current flow through the switch.

2. The circuit of claim 1 wherein the control circuit controls the solid-state switch to maintain a minimum voltage for feeding the energy harvesting circuit over a wide range of currents through the solid-state switch.

3. The circuit of claim 1 wherein the control circuit controls the switch to maintain a minimum voltage for feeding the energy harvesting circuit over a wide range of currents through the input and output of the switch.

4. The circuit of claim 1 wherein the energy harvesting circuit comprises a resonant converter having a turns ratio sufficient to convert the voltage drop for the control circuit to keep the switch in an on state while current is flowing through the switch.

5. The circuit of claim 1 and further comprising a Zener diode coupled between the energy harvesting circuit and the input to cause the switch to turn on prior to avalanche.

6. The circuit of claim 1 and further comprising a rectifier coupled to the energy harvesting circuit that activates the energy harvesting circuit in response to an AC signal across the switch to turn on the switch.

7. The circuit of claim 1 and further comprising a resonant filter coupled between the energy harvesting circuit and the switch to prevent turn on due to noise.

8. The circuit of claim 1 wherein the switch comprises a solid-state switch.

9. The circuit of claim 1 wherein the switch is configured to latch to a high impedance state in response to low current across the switch resulting in a low voltage at the gate of the switch.

10. A system comprising:
a plurality of photovoltaic (PV) modules;
a plurality of protective devices, each protective device coupled in series between two of the PV modules, forming an alternating series of PV modules and protective devices, wherein the protective devices comprise:
a switch having a high impedance latchable state;
an energy harvesting circuit coupled to the switch to collect power from the voltage drop across the switch; and
a control circuit coupled to the energy harvesting circuit to maintain the switch in an ‘on’ low impedance state in response to current flow through the switch and to turn off the switch in response to no current flow through the switch.

11. The system of claim 10 and further comprising a master switch coupled to the series string of PV modules and switches, the master switch capable of stopping current flow in the series string.

12. The system of claim 11 wherein the switches latch to the high-impedance state in response to the master switch stopping current flow.

13. The system of claim 10 wherein the energy harvesting circuits comprise a resonant converter having a turns ratio sufficient to convert the voltage drop for the control circuit to keep the switch in an on state while current is flowing through the switch.

14. The system of claim 10 and further comprising a Zener diode coupled between the energy harvesting circuit and the switch to cause the switch to turn on prior to avalanche.

15. The system of claim 10 and further comprising:
a rectifier coupled to the energy harvesting circuit that activates the energy harvesting circuit in response to an AC signal across the switch to turn on the switch; and
a resonant filter coupled between the energy harvesting circuit and the switch to prevent turn on due to noise.

16. A method comprising:
harvesting energy from a disconnect switch while DC current is flowing through the switch;
generating a supply voltage from the harvested energy;
applying a voltage to a control gate of the disconnect switch, the supply voltage being generated by a control circuit coupled to the supply voltage; and
placing the disconnect switch in a high impedance state in response to a lack of DC current flowing through the switch.

17. The method of claim 16 and further comprising placing a disconnect switch in a conductive state in response to an AC signal applied to the disconnect switch.

18. The method of claim 17 wherein the AC signal has a current between 1 mA and 1 A at 10 kHz up to 10 MHz.

19. The method of claim 16 wherein the lack of DC current is caused by using a master switch to create an open circuit in a series connected string of alternating protective devices that include switches and photo voltaic modules.

20. The method of claim 16 and further comprising:
using a Zener diode coupled to the switch to cause the switch to turn on prior to avalanche; and
using a resonant filter to prevent switch turn on due to noise.
